(19) United States
(12) Patent Application Publication
(10) Pub. No.: US 2009/0079007 A1
(43) Pub. Date: Mar. 26, 2009

(54) SEMICONDUCTOR DEVICE AND MANUFACTURING METHOD THEREOF

(75) Inventors: TADASHI YAMAGUCHI, Tokyo (JP); Keiichiro Kashihara, Tokyo (JP); Toshiaki Tsutsumi, Tokyo (JP); Tomonori Okudaira, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/211,925

(22) Filed: Sep. 17, 2008

(30) Foreign Application Priority Data
Sep. 21, 2007 (JP) 2007-244988

(51) Int. Cl. H01L 29/00; H01L 21/8238

(52) U.S. Cl. 257/370; 438/211; 257/E29.001; 257/E21.632

(57) ABSTRACT

The present invention can prevent occurrence of an off-leak current in the NMISFETs formed over the Si (110) substrate and having a silicided source/drain region. The semiconductor device includes N channel MISFETs (Metal Insulator Semiconductor Field Effect Transistors) which are formed over a semiconductor substrate having a main surface with a (110) plane orientation and have a source region and a drain region at least one of which has thereover nickel silicide or a nickel alloy silicide. Of these NMISFETs, those having a channel width less than 400 nm are laid out so that their channel length direction is parallel to a <100> crystal orientation.

### CROSS-REFERENCE TO RELATED APPLICATION

The disclosure of Japanese Patent Application No. 2007-244988 filed on Sep. 21, 2007 including the specification, drawings and abstract is incorporated herein by reference in its entirety.

### TECHNICAL FIELD

The present invention relates to a semiconductor device and a manufacturing method thereof. In particular, the invention pertains to a semiconductor device having an N-channel MISFET (Metal-Insulator Semiconductor Field Effect Transistor) formed over a semiconductor substrate having a main surface with a (110) plane orientation and having source and drain regions over which nickel (Ni) silicide or a nickel alloy silicide has been formed.

### RELATED ART

In the high precision process technology for the fabrication of semiconductor devices, particularly, SoC (System-On-Chip) devices after the 32-nm node, employment of Si substrates whose main surface has a (110) plane orientation (which will hereinafter be called “Si (110) substrates”) instead of conventional Si substrates whose main surface has a (100) plane orientation (which will hereinafter be called “Si (100) substrates”) is now under investigation. The reason for the replacement is that the high hole mobility in Si (110) substrates can improve the drive current of a P channel MISFET (for example, PMOSTFET (Positive Metal-Oxide Semiconductor Field-Effect transistor)).

On the other hand, it has been elucidated that the electron mobility decreases in Si (110) substrates, which reduces the drive current of an N channel MISFET (for example, NMOSFET (Negative Metal-Oxide Semiconductor Field-Effect Transistor)).

Formation of CMIS (Complementary Metal-Insulator Semiconductor) (for example, CMOS (Complementary Metal-Oxide Semiconductor)) over a Si (110) substrate therefore heightens the performance of a P channel MISFET used for it, but deteriorates the performance of an N channel MISFET. In short, it cannot improve the performance of the whole CMIS. Conventionally, it was therefore considered to be difficult to form CMIS on a Si (110) substrate.

Recent studies have however revealed that when a tensile stress is applied to a Si (110) substrate, the electron mobility becomes equal to or greater than that achieved by the use of a Si (100) substrate. This means that the above-described problem, that is, deterioration in the drive current can be overcome by the application of a tensile stress to the channel region of an N-channel MISFET formed over the Si (110) substrate. This technology contributes to improvement in the performance of an N channel MISFET using a Si (110) substrate and industrialization of CMIS using the Si(110) substrate which is conventionally thought to be difficult is now examined (for example, Japanese Patent Unexamined Patent Publication No. 2005-39171).

On the main surface of a Si (110) substrate, <110> and <100> crystal orientations run at right angles to one another so that a transistor formed over the Si (110) substrate has different electrical properties, depending on the channel direction of it. It is therefore necessary to know the characteristics of the transistor well, depending on the channel direction, when the transistor is formed over the Si (110) substrate.

Under such a background, nickel silicide (NiSi) or a nickel alloy silicide (element added: Pt, Hf, Er, Yb, Ti, Co, or the like) is used for the salicide (self-aligned silicide) process for preparing a silicide by a self aligned process over gate electrodes and source and drain regions of MISFET. Compared with cobalt silicide (CoSi₂) used for the conventional process, nickel silicide or nickel alloy silicide can be prepared by low-temperature heat treatment, enabling drastic improvement in the characteristics of the transistor.

A technology of making a substrate amorphous prior to silicide formation is also known (for example, Japanese Unexamined Patent Publications Nos. Hei 8(1996)-97420 and Hei 8(1996)-306802).

Moreover, the present inventors have proposed a technology of controlling an off-leak current of NMOSFET by injecting fluorine, silicon, argon or the like into source and drain regions of the NMOSFET prior to the formation of a silicide (for example, Japanese Unexamined Patent Publication No. 2007-103642).

### SUMMARY OF THE INVENTION

As described above, the performance of N channel MIS transistors using a Si (110) substrate has been improving in recent years. The present inventors however found by a test that an off-leak current increases unusually when Ni silicide is formed over source and drain regions of an N channel MISFET whose channel length direction corresponds to a <110> crystal orientation. An increase in the off-leak current causes an increase in a stand-by power and deterioration of operation reliability, leading to a decrease in the yield of the device.

The above-described test has also revealed that an unusual increase in the off-leak current occurs when the transistor has a small channel width (gate width). There is a fear of disturbing the miniaturization of semiconductor devices.

The present invention is provided in order to overcome the above-described problems. An object of the present invention is to reduce an off-leak current of an N channel MISFET formed over a Si (110) substrate and having a silicided source/drain region.

A semiconductor device according to the present invention is equipped with an N channel MISFET (Metal Insulator Semiconductor Field Effect Transistor) which is formed over a semiconductor substrate having a main surface with a (110) plane orientation and has a source region and a drain region at least one of which has thereover nickel silicide or a nickel alloy silicide. The N channel MISFET having a channel width less than 400 nm is laid out so that the channel length direction of the N channel MISFET corresponds to the <100> crystal orientation of the semiconductor substrate.

In semiconductor devices formed over a semiconductor substrate having a main surface with a (110) plane orientation, an N channel MISFET having a channel width less than 400 nm and having a channel length direction corresponding to a <110> crystal orientation causes an increase in off-leak current due to abnormal growth of nickel silicide. This problem can be overcome by changing the channel length direction of the N channel MISFET to a <100> crystal orientation.

### BRIEF DESCRIPTION OF DRAWINGS

FIG. 1 illustrates the configuration of the semiconductor device according to the present invention;

FIGS. 2(a) and 2(b) illustrate a specific example of the structure of a MOSFET;

FIG. 3 illustrates the configuration of a semiconductor device according to Embodiment 4;

FIG. 4 illustrates a manufacturing step of the semiconductor device according to Embodiment 5;

FIG. 5 illustrates a manufacturing step of the semiconductor device according to Embodiment 5 following that illustrated in FIG. 4;

FIG. 6 illustrates a manufacturing step of the semiconductor device according to Embodiment 5 following that illustrated in FIG. 5;

FIG. 7 illustrates a manufacturing step of the semiconductor device according to Embodiment 5 following that illustrated in FIG. 6;

FIG. 8 illustrates a manufacturing step of the semiconductor device according to Embodiment 5 following that illustrated in FIG. 7;

FIG. 9 illustrates a manufacturing step of the semiconductor device according to Embodiment 5 following that illustrated in FIG. 8;

FIG. 10 illustrates a manufacturing step of the semiconductor device according to Embodiment 5 following that illustrated in FIG. 9;

FIG. 11 illustrates the structure of a NMOSFET in Embodiment 7; and

FIG. 12 illustrates the structure of another NMOSFET in Embodiment 7.

### DETAILED DESCRIPTION OF THE PREFERRED EMBODIMENTS

The test made by the present inventors have revealed that the above-described problem of an unusual increase in off-leak current occurs when the channel width (gate width) of a MISFET is less than 400 nm and it is marked particularly when the channel width is not greater than 150 nm; and that a P channel MISFET or an N channel MISFET having a channel length direction parallel to the <100> crystal orientation is free from such a problem. In short, an unusual increase in an off-leak current is a problem peculiar to an N channel MISFET formed over a Si (110) substrate and having a channel length direction parallel to a <110> crystal orientation.

As a result of more detailed analysis by the present inventors, it has been elucidated that the above-described problem occurs due to an abnormal growth of thermally unstable NiSi toward the <110> crystal orientation during a heat treatment step (for example, annealing for the formation of silicide or heat treatment in a metallization step). This is the reason why the unusual increase in an off-leak current is a problem peculiar to the MISFET having a channel length direction parallel to a <110> crystal orientation.

The above test has also revealed that an unusual increase in an off-leak current can be prevented by making the main surface of a Si (110) substrate amorphous prior to the preparation of a silicide over the source/drain region.

In the embodiments descried below, a description will be made on a MOSFET which is a typical example of MISFETs. It should however be noted that the present invention can be applied not only to it but also widely to MISFETs.

### Embodiment 1

The semiconductor device according to Embodiment 1 of the present invention is formed over an Si (110) substrate and is equipped with a plurality of MOSFETs having source and drain regions, at least one of which has thereover nickel silicide or a nickel alloy silicide (element added: Pt, Hf, Er, Yb, Ti, Co or the like) (both nickel silicide and nickel alloy silicides will hereinafter be called “nickel silicide”, collectively). Of the MOSFETs, those having a channel width (gate width) less than 400 nm are laid out so that the channel length direction (gate length direction) is parallel to a <100> crystal orientation.

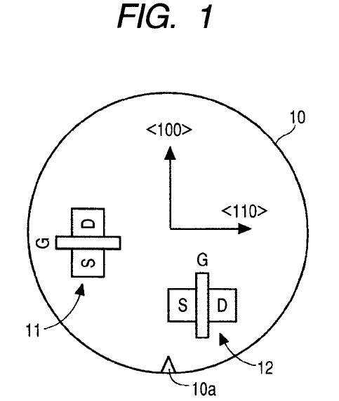

FIG. 1 is a diagram for illustrating the configuration of the semiconductor device according to Embodiment 1. FIG. 1 illustrates <110> crystal orientation and <100> crystal orientations on the Si (110) substrate 10. The wafer of the Si (110) substrate 10 has a notch 10a in the direction of the <100> crystal orientation. FIG. 1 schematically illustrates an MOSFET 11 (which will hereinafter be called “<100> channel MOSFET”) having a channel length direction parallel to the <100> crystal orientation and an MOSFET 12 (which will hereinafter be called “<110> channel MOSFET”) having a channel length direction parallel to the <110> crystal orientation.

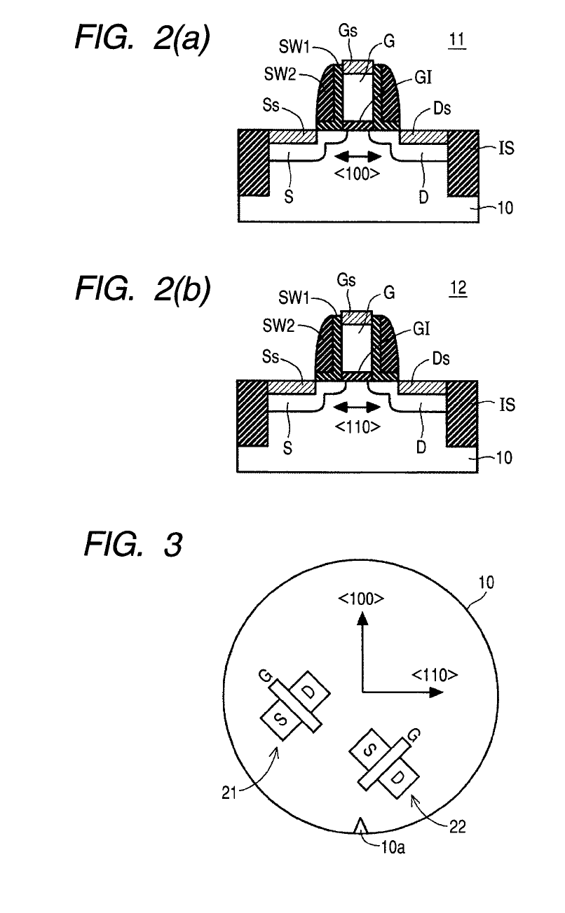

FIGS. 2(a) and 2(b) specifically illustrate the structures of the <100> channel MOSFET 11 and the <110> channel MOSFET 12, respectively. As can be understood from FIGS. 2(a) and 2(b), the <100> channel MOSFET 11 and the <110> channel MOSFET 12 have basically the same structure, though different in channel length direction. Described specifically, the MOSFETs 11 and 12 are formed in an active region defined by isolation insulating films IS. The MOSFETs 11 and 12 are both equipped with a gate electrode G formed over the Si (110) substrate 10 via a gate insulating film GI, and a source region S and a drain region D formed in the upper portion of the Si (110) substrate 10 with the gate electrode G therebetween.

For the convenience of description, a PMOSFET is not distinguished from a NMOSFET in FIGS. 1 and 2, but the source region S and the drain region D are p type impurity regions in the PMOSFET, while they are n type impurity regions in the NMOSFET.

In this example, two-layer structured sidewalls having a first sidewall SW1 made of a silicon oxide film and a second sidewall SW2 made of a silicon nitride film are formed over each of the side surfaces of the gate electrode G. Silicides Gs, Ss, and Ds are formed by a self-aligned process over the gate electrode G, the source region S, and the drain region, respectively. These silicides Gs, Ss, and Ds are each nickel silicide (nickel silicide or nickel alloy silicide).

As defined in FIG. 1, the channel length direction of the <100> channel MOSFET 11 illustrated in FIG. 2(a) is parallel to a <100> crystal orientation, while the channel length direction of the <110> channel MOSFET 12 illustrated in FIG. 2(b) is parallel to a <110> crystal orientation. When a plurality of MOSFETs is laid out over a substrate, it is the common practice to use two types of MOSFETs different in channel length direction by 90 degree. In this Embodiment, the above-described <100> channel MOSFET 11 and the <110> channel MOSFET 12 are used.

As described above, the MOSFETs having a channel width less than 400 nm, among the plurality of MOSFETs, are laid out so that their channel length direction is parallel to a <100> crystal orientation (the <100> channel MOSFET 11 is employed as the MOSFET having a channel width less than 400 nm). An unusual increase in the off-leak current is a problem peculiar to an N channel MISFET having a channel width less than 400 nm and having a channel length direction parallel to a <110> crystal orientation. This problem can therefore be prevented by the use of the <100> channel MOSFET 11 as the MOSFET having a channel width less than 400 nm.

The channel length direction of MOSFETs having a channel width of 400 nm or greater is not limited. Either the <100> channel MOSFET 11 or the <110> channel MOSFET 12 may be employed as such MOSFETs. This prevents excessive limitation of layout freedom.

When the channel width becomes 150 nm or less, the unusual increase in an off-leak current occurs markedly. Accordingly, in order to attach importance to the layout freedom while allowing a certain degree of an off-leak current, only MOSFETs having a channel width less than 150 nm are limited to those having a channel length direction parallel to a <100> crystal orientation. In other words, MOSFETs having a channel width less than 150 nm are laid out as the <100> channel MOSFET 11, while the other MOSFETs are laid out either as the <100> channel MOSFET 11 or the <110> channel MOSFET 12. This improves layout freedom and contributes to high density integration and easy designing of the semiconductor device according to the present invention.

### Embodiment 2

Memory cells such as SRAM are required to be mounted with a high density so that MOSFETs used for these memory cells must be minute and have a channel width less than 400 nm (more preferably, 150 nm or less). According to this Embodiment, in the semiconductor device using the Si (110) substrate 10, all the MOSFETs used for memory cells are therefore aligned so that their channel length direction is parallel to the <100> crystal orientation. In short, each memory cell is laid out as the <100> channel MOSFET 11. The MOSFET of a peripheral circuit other than the memory cell is laid out either as the <100> channel MOSFET 11 or the <110> channel MOSFET 12.

According to Embodiment 2, in the semiconductor device using the Si (110) substrate, an unusual increase of an off-leak current in memory cells can be prevented. As described above, minute transistors are used for the memory cells so that such a layout is effective. In the peripheral circuit, on the other hand, the channel length direction of the MOSFET is not limited so that layout freedom in the peripheral circuit is not impaired. The MOSFET used in the peripheral circuit is not so minute so that an unusual increase of an off-leak current may hardly occur and pose a problem.

### Embodiment 3

In Embodiment 1, the MOSFET having a channel width less than 400 nm is aligned irrespective of the conductivity type of the MOSFET so that its channel length direction is parallel to the <100> crystal orientation. In Embodiment 2, the MOSFET to be used for a memory cell is aligned irrespective of the conductivity type of the MOSFET so that its channel length direction is parallel to the <100> crystal orientation. As described, however, the test made by the present inventors has revealed that an unusual increase of an off-leak current is a problem peculiar to the NMOSFET. Embodiment 3 is similar to Embodiments 1 and 2 except that the channel length direction of only the N-channel MOSFET is limited to the <100> crystal orientation.

For example, in Embodiment 3, the channel length direction of the PMOSFET of Embodiment 1 is not limited to the <100> crystal orientation or the <110> crystal orientation even if it has a channel width less than 400 nm (or 150 nm or less). On the other hand, the channel length direction of the PMOSFET of Embodiment 2 is not limited to the <100> crystal orientation or the <110> crystal orientation even if it is used for memory cells. Thus, in Embodiment 3, the channel length direction of the PMOSFET is not limited so that the layout freedom of MOSFETs can be improved further.

When the channel length direction of the NMOSFET and the channel length direction of the PMOSFET are aligned as in Embodiments 1 and 2, the structure and layout of CMOS can be simplified relatively, which contributes to simplification of the design and the manufacturing steps of the semiconductor device.

### Embodiment 4

When a plurality of MOSFETs is laid out over a substrate, it is the common practice to use MOSFETs different in the channel length direction by 90 degree. In Embodiments 1 to 3, the <100> channel MOSFET 11 and the <110> channel MOSFET 12 illustrated in FIGS. 1 and 2 are used as MOSFETS to be formed over the Si (110) substrate 10.

In Embodiment 4, as illustrated schematically in FIG. 3, two MOSFETS, that is, a MOSFET 21 having a channel length direction 45 degrees to the <110> crystal orientation and a MOSFET 22 having a channel length direction 90 degrees to the MOSFET 21 are used (as a result, the channel length direction of the MOSFET 22 is also 45 degrees to the <110> crystal orientation).

According to Embodiment 4, the channel length direction of the MOSFETs laid out over the Si (110) substrate 10 is not parallel to the <110> crystal orientation so that an unusual increase of an off-leak current in the NMOSFETs can be prevented.

Also in this Embodiment, when the NMOSFET and the PMOSFET have the same channel length direction, the resulting CMOS has a relatively simple structure and layout, which contributes to simplification of the design and manufacturing steps of the device.

### Embodiment 5

The test by the present inventors have revealed that an unusual increase of an off-leak current in NMOSFETs having a channel width less than 400 nm (especially, 150 nm or less) is attributable to an abnormal growth of nickel silicide over the source/drain region. A further investigation has revealed that by making the source/drain region amorphous prior to the formation of nickel silicide, an abnormal growth of nickel silicide can be prevented and as a result, an unusual increase of an off-leak current can be prevented.

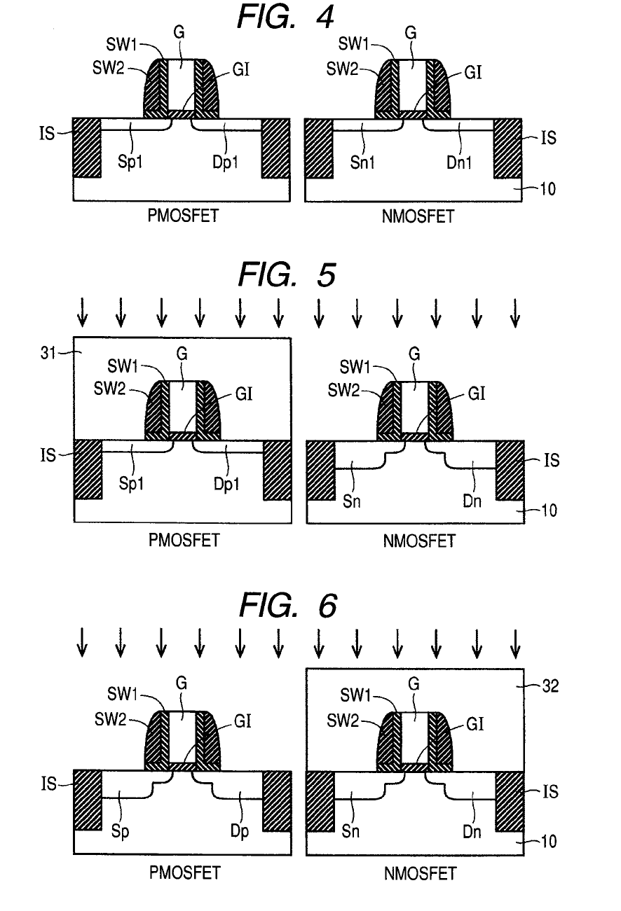

FIGS. 4 to 10 illustrate manufacturing steps of the semiconductor device according to Embodiment 5 of the present invention. The manufacturing method of the semiconductor device according to Embodiment 5 will hereinafter be described referring to accompanying drawings.

As illustrated in FIG. 4, a PMOSFET and a NMOSFET each including a stack structure of a gate insulating film GI and a gate electrode G, a first sidewall SW1, a second sidewall SW2, a LDD (lightly Doped Drain) region for source, and a LDD region for drain are formed over an Si (110) substrate 10 by photolithography, etching, ion implantation, and the like.

The LDD regions must be formed properly so that the LDD region Sp1 for source and the LDD region Dp1 for drain, each of the PMOSFET, become P type regions and the LDD region Sn1 for source and the LDD region Dn1 for drain, each of the NMOSFET, become N type regions. They can therefore be formed by selective ion implantation with a photomask.

As illustrated in FIG. 5, a resist mask 31 which covers a PMOSFET forming region and exposes a NMOSFET forming region is prepared. With the resulting resist mask as a mask, a predetermined dopant is injected into the Si (110) substrate 10 to form a source region Sn and a drain region Dn for the NMOSFET. Injection may be conducted, for example, using As (arsenic) ions as the dopant at an injection energy of from 5 to 20 keV and a dose of from 1×10¹⁵ to 1×10¹⁶ cm⁻² or using P (phosphorus) ions as the dopant at an injection energy of from 5 to 10 keV and a dose of from 1×10¹⁴ to 1×10¹⁵ cm⁻².

After removal of the resist mask 31, a resist mask 32 which covers the NMOSFET forming region and exposes the PMOSFET forming region as illustrated in FIG. 6 is prepared. With the resulting resist mask as a mask, a predetermined dopant is injected into the Si (110) substrate 10 to form a source region Sp and a drain region Dp for the PMOSFET. Injection may be conducted, for example, using B (boron) ions as the dopant at an injection energy of from 0.5 to 2 keV and a dose of from 1×10¹⁵ to 1×10¹⁶ cm⁻².

After removal of the resist mask 32, the source regions Sp and Sn and the drain regions Dp and Dn are activated by spike annealing (which means extremely-short rapid thermal treatment at a temperature raised to from 900 to 1000° C.).

The step of forming the source region Sp and the drain region Dp of the PMOSFET and the step of forming the source region Sn and the drain region Dn of the NMOSFET are performed in any order.

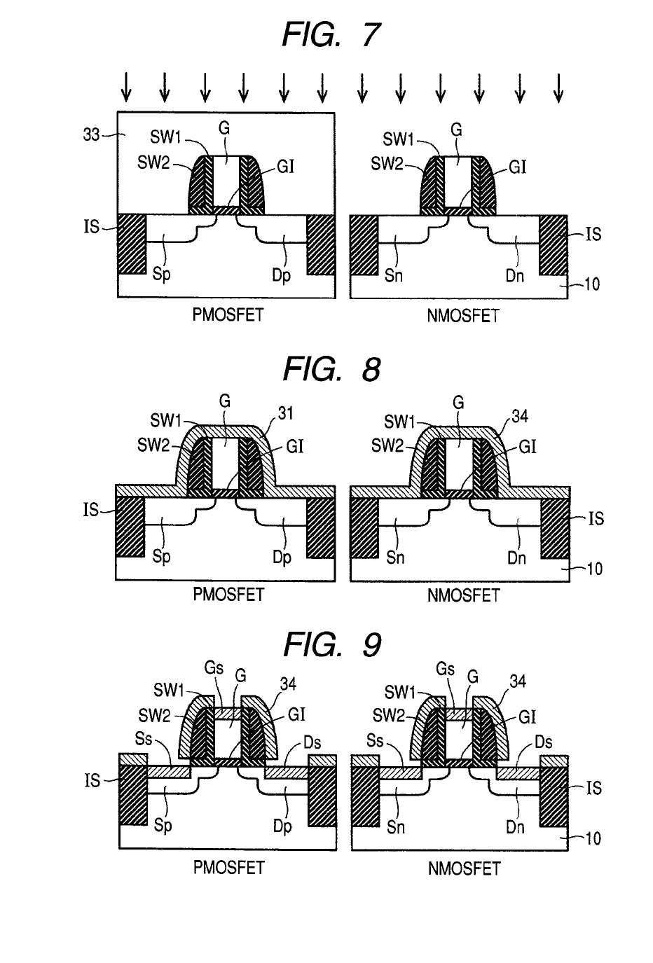

A resist mask 33 which covers the PMOSFET forming region and exposing the NMOSFET forming region is then formed. With the resulting resist mask as a mask, ions are injected into the Si (110) substrate 10 to make the source region Sn and the drain region Dp of the NMOSFET amorphous (FIG. 7).

As the ions, fluorine ions and/or silicon ions can be injected. Irrespective of whether fluorine ions or silicon ions are used, injection may be conducted at injection energy of 5 keV and a dose of from approximately 6×10¹⁴ to 1×10¹⁵ cm⁻². It is also possible to inject ions containing at least one of C (carbon), Ge (germanium), Ne (neodium), Ar (argon), and Kr (krypton) in addition to fluorine or silicon ions.

Prior to a subsequent silicidation step, a pre-cleaning step is performed for removing a silicon oxide film and the like formed at a portion to be silicided such as surface of the Si (110) substrate 10 or gate electrode 10. This pre-cleaning step may include RCA cleaning and cleaning with hydrofluoric acid. Alternatively, the pre-cleaning may be performed with an integrated combination of a pre-cleaning (chemical dry cleaning) apparatus and a sputtering apparatus.

As illustrated in FIG. 8, a nickel film (or a nickel alloy film) 34 is formed over the surface of the Si (110) substrate 10 by sputtering. The nickel film 34 thus formed may have a thickness of from 8.0 to 12.5 nm.

First RTA (Rapid Thermal Annealing) is then performed. The first RTA is performed at from 250 to 350° C. for from 30 to 60 seconds in an N₂ atmosphere by lamp annealing or the like. By this annealing, the nickel film 34 reacts with the surfaces of the gate electrode G, source regions Sp and Sn, and drain regions Dp and Dn of the PMOSFET and the NMOSFET to form silicides Gs, Ss, and Ds as illustrated in FIG. 9. At this time, however, the silicides Gs, Ss and Ds each has a stoichiometric composition of Ni₂Si.

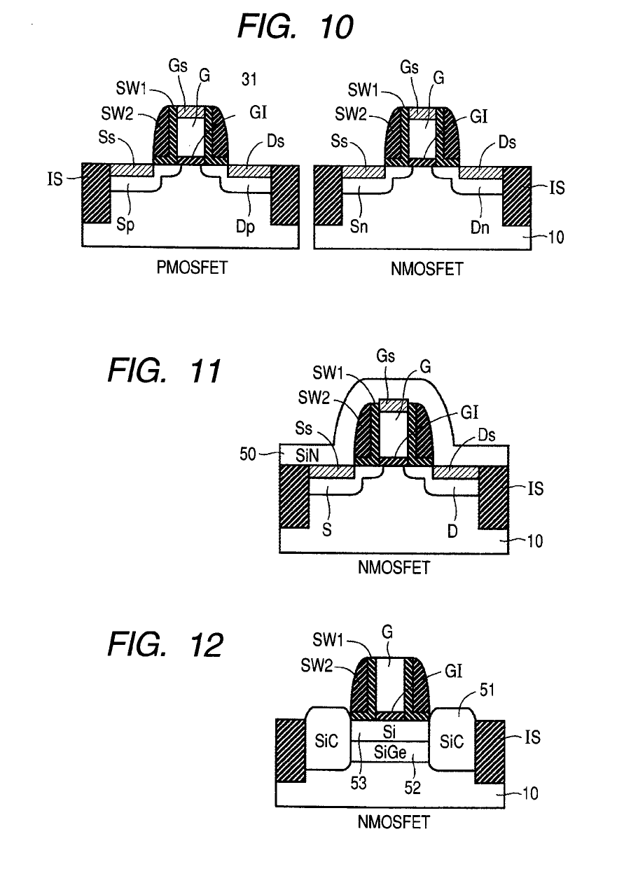

An unreacted nickel film 34 is then removed (FIG. 10). The removal can be effected by dipping the Si (110) substrate 10 in a mixture of sulfuric acid, hydrogen peroxide, and water for from 30 to 60 minutes.

A second (final) RTA is then performed. The second RTA is performed at from 350 to 450° C. for from 30 to 60 seconds in an N₂ atmosphere by lamp annealing or the like to accelerate the reaction between nickel and silicon in the silicides Gs, Ss, and Ds. As a result, the silicides Gs, Ss, and Ds each has a stoichiometric composition of NiSi.

By the above-described steps, the NMOSFET according to the present embodiment as well as the PMOSFET are formed over the Si (110) substrate 10.

The above-described manufacturing method include two heat treatment (RTA) steps for silicidation. When the first RTA is performed at a high temperature (approximately 450° C.) to form silicides Gs, Ss, and Ds having an NiSi phase, the second RTA can be omitted.

According to the manufacturing method of Embodiment 5, prior to the step (FIGS. 8 and 9) of forming nickel suicides Ss and Ds in the source region Sn and drain region Dn of the NMOSFET formed over the Si (110) substrate 10, the source region Sn and the drain region Dn are made amorphous (FIG. 7). By making these regions amorphous, an abnormal growth of the nickel silicides Ss and Ds can be prevented even if the channel direction of the NMOSFET is parallel to the <110> crystal orientation. As a result, an unusual increase in the leak current of the NMOSFET can be prevented.

Ion implantation into the source and drain regions of the MOSFET to make it amorphous sometimes deteriorates the electrical properties of the MOSFET (for example, increase the resistance of the source and drain regions). The treatment for making the source and drain regions amorphous according to this Embodiment is not necessarily performed for all of the NMOSFETs but may be performed selectively only for the NMOSFETs which may cause an unusual increase of an off-leak current, that is, the NMOSFETs having a channel width less than 400 nm (particularly, not greater than 150 nm), or the NMOSFETs having a channel length direction parallel to the <110> crystal orientation. In this case, in the ion implantation step (FIG. 7) for making the source and drain regions amorphous, the resist mask 33 may be formed also over the NMOSFET not subjected to this treatment.

### Embodiment 6

As described above, since memory cells are required to achieve high density integration, MOSFETs having a channel width as minute as less than 400 nm (more preferably, not greater than 150 nm) are used for the memory cells. In this Embodiment 6, Embodiment 5 is applied only to the MOSFETs used for memory cells of a semiconductor device using a Si (110) substrate. Described specifically, the source and drain regions of the NMOSFETs used for memory cells is made amorphous by ion implantation prior to the silicidation step. On the other hand, the MOSFETs of the peripheral circuits other than the memory cells are not subjected to the treatment for making the source and drain regions amorphous

According to Embodiment 6, an unusual increase of an off-leak current in the memory cell is prevented in the semiconductor device using the Si (110) substrate 10. This Embodiment is effective, because minute transistors are used for the memory cells. In the MOSFETs of the peripheral circuit, the source and drain regions are not made amorphous so that deterioration in electrical properties of the MOSFETs (for example, resistance rise in the source and drain regions) attributable to the above-described treatment can be prevented. The MOSFETs used in the peripheral circuit are not so minute so that an unusual increase of an off-leak current may hardly occur and pose a problem.

### Embodiment 7

As described above, when the Si (110) substrate 10 is used, the electron mobility decreases so that the drive current of NMOSFETs decreases. The electron mobility can be raised and a reduction in the drive current can be prevented by generating a tensile stress in the channel region of the NMOSFETs. Such a technology for applying a stress to a silicon substrate is known as “strained silicon technology” and it has now attracted attentions as a technology for realizing satisfactory carrier mobility and drive current in semiconductor devices of the next generation. In Embodiment 7, examples of the strained silicon technology applicable to NMOSFETs of the present invention will next be described.

One example is illustrated in FIG. 11. By covering the upper portion of the NMOSFET with a liner film 50 (nitride film) which generates a tensile stress as illustrated in FIG. 11, the tensile stress can be applied to the channel region of the NMOSFET. This liner film 50 can be used also as an etching stopper during formation of contacts. This technology is known as a simple and low cost technology and can be applied readily to the present invention.

Another example is illustrated in FIG. 12. As illustrated in FIG. 12, the source and drain regions of the NMOSFET are etched and they are replaced by a SiC layer 51. Since Si in the lattice is substituted with C in the source and drain regions having therebetween a Si layer 53 of the channel region owing to the lattice constant of C smaller than that of Si, a tensile stress is applied to the Si layer 53 in the channel region.

In addition, a SiGe layer 52 is filled below the Si layer 53 of the channel region. Since the lattice constant of Ge is greater than that of Si and Si in the lattice below the Si layer 53 of the channel region is replaced by Ge, a tensile stress is applied to the Si layer 53.

The technology illustrated in FIG. 12 enables a further increase in the tensile stress applied to the Si layer 53 in the channel region, which is produced by a synergistic effect between the SiC layer 51 and the SiGe layer. The technology illustrated in FIG. 11 cannot apply a sufficiently strong stress to the channel region when the length of the source and drain regions of the transistor decreases as a result of high integration degree of a semiconductor device. According to the technology illustrated in FIG. 12, on the other hand, a strong stress can be applied stably to the channel region even in such a case so that it is expected to produce high effects even when the technology is used for a minute transistor as that of the present invention.

1. A semiconductor device comprising:
a semiconductor substrate having a main surface with a (110) plane orientation; and
an N channel MISFET (Metal Insulator Semiconductor Field Effect Transistor) formed over the main surface and having a source region and a drain region at least one of which has thereover nickel silicide or a nickel alloy silicide,
wherein the N channel MISFET has a channel width less than 400 nm and is laid out so that a channel length direction of the N channel MISFET is parallel to a <100> crystal orientation of the semiconductor substrate.

2. The semiconductor device according to claim 1, further comprising a P channel MISFET which forms a CMIS (Complementary Metal-Insulator Semiconductor) together with the N channel MISFET,
wherein the P channel MISFET is laid out so that a channel length direction of the P channel MISFET is parallel to the <100> crystal orientation of the semiconductor substrate.

3. A semiconductor substrate comprising:
a semiconductor substrate having a main surface with a (110) plane orientation; and
an N channel MISFET (Metal Insulator Semiconductor Field Effect Transistor) formed over the main surface and having a source region and a drain region at least one of which has thereover nickel silicide or a nickel alloy silicide,
wherein the N channel MISFET has a channel width less than 400 nm and is laid out so that a channel length direction of the N channel MISFET is 45 degrees to a <100> crystal orientation of the semiconductor substrate.

4. The semiconductor device according to claim 3, further comprising a P channel MISFET which forms a CMIS (Complementary Metal-Insulator Semiconductor) together with the N channel MISFET,
wherein the P channel MISFET is laid out so that a channel length direction of the P channel MISFET is 45 degrees to the <100> crystal orientation of the semiconductor substrate.

5. A semiconductor device comprising:
a semiconductor substrate having a main surface with a (110) plane orientation; and
a plurality of memory cells formed over the main surface and having an N channel MISFET,
wherein all the N channel MISFETs included in the memory cells are laid out so that channel length directions of the N channel MISFETs are arrayed parallel to a <100> crystal orientation of the semiconductor substrate.

6. The semiconductor device according to claim 5, wherein each of the N channel MISFETs included in the memory cells has a source region and a drain region at least one of which has thereover nickel silicide or a nickel alloy silicide.

7. The semiconductor device according to claim 5, wherein all of the MISFETs included in the memory cells are laid out so that the channel length directions of the MISFETs are arrayed parallel to the <100> crystal orientation of the semiconductor substrate.

8. The semiconductor device according to claim 5, further comprising a peripheral circuit,
wherein the peripheral circuit has an N channel MISFET laid out so that a channel length direction of the N channel MISFET is parallel to a <110> crystal orientation of the semiconductor substrate.

9. A manufacturing method of a semiconductor device, comprising the steps of:
(a) forming an N channel MISFET (Metal Insulator Semiconductor Field Effect Transistor) over a semiconductor substrate having a main surface with a (110) plane orientation;
(b) implanting ions to make a source region and a drain region of the N channel MISFET amorphous; and
(c) after the step (b), forming nickel silicide or a nickel alloy silicide over the source region and the drain region of the N channel MISFET.

10. The manufacturing method of a semiconductor device according to claim 9,
wherein in the step (a), P channel MISFET is formed together with the N channel MISFET,
wherein step (d) of forming a resist covering therewith the P channel MISFET is performed prior to the step (b), and
wherein ion implantation of the step (b) is performed with the resist as a mask.

11. The manufacturing method of a semiconductor device according to claim 9,
wherein the semiconductor device comprises a memory cell, and
wherein the step (b) is performed only for the N channel MISFET forming the memory cell.
